(19) United States
(12) Patent Application Publication
(10) Pub. No.: US 2026/0297801 A1
(43) Pub. Date: Oct. 1, 2026

(54) Modifying Crystal Growth Processes Based on Predicted In Situ Parameters

(71) Applicant: Wolfspeed, Inc., Durham, NC (US)

(72) Inventors: Steven Herbert Griffiths, Morrisville, NC (US); Caleb Andrew Kent, Durham, NC (US); Ramya Lakshmi Gurunathan, Cary, NC (US); Michael Anthony Fusco, Wake Forest, NC (US); Matthew David Conrad, Cary, NC (US); David Aries Deininger, Cary, NC (US)

(21) Appl. No.: 19/213,608

(22) Filed: May 20, 2025

Related U.S. Application Data
(60) Provisional application No. 63/779,902, filed on Mar. 28, 2025.

(51) Int. Cl. C30B 23/00; C23C 14/06; C23C 14/24; C23C 14/54; C30B 23/06; C30B 29/36

(52) U.S. Cl. CPC C30B 23/002; C23C 14/0635; C23C 14/24; C23C 14/54; C30B 23/06; C30B 29/36

(57) ABSTRACT

An example method includes obtaining, during a crystal growth process of a crystalline material, one or more ex situ parameters of a crystal growth system associated with the crystal growth process. The example method includes determining, based at least in part on the one or more ex situ parameters, a predicted in situ parameter. The example method includes adjusting, based at least in part on the predicted in situ parameter, one or more process parameters of the crystal growth process.

### PRIORITY CLAIM

The present application claims the benefit of priority of U.S. Provisional Application Ser. No. 63/779,902, filed on Mar. 28, 2025, which is incorporated herein by reference.

### FIELD

The present disclosure relates generally to crystal growth systems, such as silicon carbide crystal growth systems for growing crystalline silicon carbide semiconductor workpieces for fabrication of semiconductor devices.

### BACKGROUND

Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), bipolar junction transistors (“BJTs”), Insulated Gate Bipolar Transistors (“IGBT”), Gate Turn-Off Transistors (“GTO”), junction field effect transistors (“JFET”), high electron mobility transistors (“HEMT”) and other devices. Example semiconductor devices may be diodes, such as Schottky diodes or other devices.

Power semiconductor devices may be packaged into various semiconductor device packages, such as discrete semiconductor device packages and power modules. Power modules may include one or more power devices and other circuit components and can be used, for instance, to dynamically switch large amounts of power through various components, such as motors, inverters, generators, and the like.

### SUMMARY

Aspects and advantages of embodiments of the present disclosure will be set forth in part in the following description, or can be learned from the description, or can be learned through practice of the embodiments.

In an aspect, the present disclosure provides an example method. In some implementations, the example method includes obtaining, during a crystal growth process of a crystalline material, one or more ex situ parameters of a crystal growth system associated with the crystal growth process. In some implementations, the example method includes determining, based at least in part on the one or more ex situ parameters, a predicted in situ parameter. In some implementations, the example method includes adjusting, based at least in part on the predicted in situ parameter, one or more process parameters of the crystal growth process.

In an aspect, the present disclosure provides an example method. In some implementations, the example method includes obtaining ex situ data associated with a crystal growth system used to grow a crystalline material. In some implementations, the example method includes training a machine-learning model to predict an in situ parameter during a crystal growth process using the ex situ data associated with the crystal growth system.

In an aspect, the present disclosure provides a system. The system includes processing circuitry configured to perform operations. The operation comprise: obtaining, during a crystal growth process of a crystalline material, one or more ex situ parameters of a crystal growth system associated with the crystal growth process; determining, based at least in part on the one or more ex situ parameters, a predicted in situ parameter; and adjusting, based at least in part on the predicted in situ parameter, one or more process parameters of the crystal growth process.

In an aspect, the present disclosure provides an example method. In some implementations, the example method includes obtaining, during a crystal growth process of a crystalline material, one or more operation parameters of a crystal growth system associated with the crystal growth process. In some implementations, the example method includes determining, based on the one or more operation parameters, a predicted crystal parameter. In some implementations, the example method includes adjusting, based on the predicted crystal parameter, one or more process parameters of the crystal growth process.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a system for real-time monitoring of crystal growth processes according to example aspects of the present disclosure.

FIG. 2 depicts a cross-sectional schematic diagram of an example crystal growth system for use in a crystal growth process according to example aspects of the present disclosure.

FIGS. 3A and 3B depict a cross-sectional schematic diagram of an example crystal growth system during various segments of a crystal growth process according to example aspects of the present disclosure.

FIGS. 4A and 4B depict example crystal growth system control logic diagrams according to example aspects of the present disclosure.

FIG. 5 depicts a block diagram of an example method according to example aspects of the present disclosure.

FIG. 6 depicts a block diagram of an example method according to example aspects of the present disclosure.

FIG. 7 depicts a block diagram of an example computing system according to example aspects of the present disclosure.

FIGS. 8, 9, 10, 11, 12, 13, and 14 depict example crystal growth systems that may implement the systems and methods according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Example aspects of the present disclosure are directed to systems and methods for growing semiconductor crystalline material, such as crystalline silicon carbide (SiC) (e.g., single crystal SiC). Semiconductor devices may be fabricated from wide bandgap semiconductor materials, such as silicon carbide and/or Group III nitride-based semiconductor materials. The fabrication process for power semiconductor devices may require processing of wide bandgap semiconductor wafers, such as silicon carbide semiconductor wafers.

Aspects of the present disclosure are discussed with reference to growing silicon carbide (SiC) crystalline material. Those of ordinary skill in the art, using the disclosures provided herein, will understand that aspects of the present disclosure may be used with crystal growth systems for growing other types of crystalline material, such as aluminum nitride (AlN) or other materials.

Single crystal silicon carbide (SiC) has proven to be a very useful wafer material in the manufacture of such semiconductor devices. Due to its physical strength and thermal properties, SiC may be used to fabricate very robust substrates adapted for use in the semiconductor industry. SiC has excellent properties, including radiation hardness, high breakdown field, a relatively wide band gap, high saturated electron drift velocity, high-temperature operation, and absorption and emission of high-energy photons in the blue, violet, and ultraviolet regions of the optical spectrum.

SiC crystalline material may be produced using various crystal growth processes. In a typical SiC growth process, a seed material and source material are arranged in a reaction crucible of a crystal growth chamber which is then heated to the sublimation temperature of the source material. By controlled heating of the environment surrounding the reaction crucible, a thermal gradient is developed between the sublimating source material and the marginally cooler seed material. By means of the thermal gradient, source material in a vapor phase is transported onto the seed material where it condenses to grow a bulk crystalline boule. This type of crystal growth process is commonly referred to as physical vapor transport (PVT) process. Additionally, in some instances, a crystal growth process may comprise a plurality of growth segments. For instance, the crystal growth process may comprise several growth segments, where each growth segment has independent process parameters such as duration, temperature, pressure, flow rate, crucible position, heater position, and/or heater position relative to crucible position, insulation position, etc.

A resulting SiC crystalline material (e.g., boule) may then be sliced into wafers, and the individual wafers may then be used as seed material for a seeded sublimation growth process, or as substrates upon which a variety of semiconductor devices (e.g., power semiconductor devices and optical applications, such as LEDs, windows, photo-diodes, etc.) may be formed.

Variations in crystal parameters (e.g., height, mass, growth rate, shape, crystal stress, doping density, etc.) may lead to variations in yield in crystal growth processes. The quality of the SiC crystalline material (e.g., boule) can vary along the height of the crystalline material (e.g., boule). As used herein, “quality” of the SiC crystal may refer to various aspects of a crystal that impact yield of the crystal and may refer, for example, to dislocation density, micropipe distribution, and other measurable descriptors associated with the crystal. Discrepancies in crystal quality may be due to changes or variations in growth conditions as the process progresses.

For example, temperature gradients may shift slightly or impurities may accumulate, leading to defects in certain regions of the crystalline material. The lower and upper parts of the boule might exhibit more defects than a middle section. This can be because as the height of the crystalline material (e.g., boule) increases, thermal stress can build up due to temperature differentials within the crystal. This can lead to cracking or other structural issues, particularly near the top of the crystalline material (e.g., boule). Accordingly, taller crystalline material (e.g., boules) may also experience significant variations in temperature and gas flow dynamics, leading to non-uniform growth rates and increased defect density in certain areas. Additionally, variations in yield, including variations in quality, may occur between growth cycles and across various crystal growth systems and systems. Crystal yield consistency may be improved by selecting appropriate growth methods (e.g., process recipes) based on the crystal growth cycle and crystal growth system, however not all inconsistencies may be eliminated.

Therefore, in situ monitoring of crystal growth cycles across various crystal growth systems may provide for improved crystal yield and reduced inconsistencies. However, the extreme conditions necessary to grow SiC crystals provide unique challenges and limitations. For instance, the high temperatures (e.g., excess of 2000 degrees Celsius) and low pressure (e.g., sub 10 torr) requirements of growth processes, such as PVT processes, pose challenges for most candidate sensing devices for monitoring and measuring crystal growth.

A potential candidate for in situ monitoring, capable of withstanding the harsh conditions of the growth processes, involves x-ray tomography imaging. In this embodiment, various x-ray tomography images of a SiC crystal may be obtained during a crystal growth process. The x-ray tomography images may be taken periodically throughout the crystal growth process to record various heights of the SiC crystal at different points during the growth process. While this candidate method may facilitate in situ monitoring, it has several drawbacks. For instance, x-ray tomography imaging is a very costly imaging technique and may require the incorporation of costly equipment in crystal growth systems, making this solution difficult to scale in production environments having hundreds or even thousands of crystal growth systems. Moreover, implementing safety constraints associated with x-ray tomography imaging may lead to further costs in implementation.

Accordingly, example aspects of the present disclosure are directed to systems and methods for in situ monitoring and modification of crystal growth processes without requiring in situ measurements associated with the crystal growth process. For instance, examples of the present disclosure are directed to using parameters that are more easily measured external to the crystal growth process (e.g., ex situ parameters) to predict in situ measurements associated with the crystal growth process.

Ex situ parameters are parameters or variables measured or controlled outside the immediate processing environment, such as outside a reaction crucible, before, during or after a crystal growth process. In situ parameters are parameters or variables directly within the processing environment, such as inside a reaction crucible, in real time during a process, such as a crystal growth process.

In some examples, the ex situ parameters are operation parameters associated with operation of the crystal growth system. Operation parameters are any parameters associated with a crystal growth system and/or operation of a crystal growth system. Operation parameters may include, for instance, temperature of one or more components of the crystal growth system (e.g., heater temperature, crucible temperature, insulation temperature), power consumption of the heaters, chemical composition of species entering the chamber, mass flow of species entering the chamber, coolant temperature, coolant flow rate, insulation displacement, pressure changes in the crystal growth system, or other suitable measurable or controllable parameters associated with operation of the crystal growth system, for instance, during a crystal growth process. Operation parameters may include information or data associated with components external to the reaction crucible (e.g., heater element temperature, heater element power consumption, coolant temperature, coolant flow rate, mass flow of species into the chamber, etc.).

In some embodiments, using one or more ex situ parameters of a crystal growth system, in situ parameters may be determined (e.g., using a model such as a machine-learning model) without requiring physical measurement of the in situ parameters. Example in situ parameters that may be predicted according to examples of the present disclosure include crystal parameters, insulation parameters, interface structure parameters, source parameters, etc. Crystal parameters are parameters associated with the crystalline material grown during the crystal growth process. Example crystal parameters include height, mass, shape, growth rate, doping, crystal stress, one or more optical properties, uniformity, etc., of the crystalline material during a crystal growth process. Example insulation parameters include one or more of a temperature of the insulation during a crystal growth process or degradation of insulation during a crystal growth process. Example interface structure parameters include one or more of a temperature of the interface structure during a crystal growth process or degradation of the interface structure during the crystal growth process, etc. Example source parameters include one or more of a source temperature, source depletion, etc., during the crystal growth process.

According to examples of the present disclosure, one or more process parameters of a crystal growth process may be adjusted based on the predicted crystal parameters (height, mass, shape, growth rate, doping, crystal stress, one or more optical properties, uniformity, etc.). Process parameters are any parameters that may be controlled during a crystal growth process to affect crystal growth. Example process parameters include temperature, pressure, coolant flow rate, flux, growth segment time duration, heater position, crucible position, crucible position relative to heater position, crystal position, source position, rotation of the crystal, and/or any of the controllable operation parameters provided herein (e.g., heater element temperature, heater element power consumption, mass flow rate of species into the chamber, etc.). The process parameter may be any controllable process variable or combination of process variables used to affect a crystal growth process.

Systems and methods according to example aspects of the present disclosure may periodically obtain data associated with ex situ parameters (e.g., operation parameters) from a crystal growth system before, during, or after a crystal growth process and provide the data to a model (e.g., physics-based model, machine learning model, physics-informed machine learned model) which may output a predicted in situ parameter (e.g., crystal parameter) indicative of a real time in situ condition during the crystal growth process. Based on the output from the model, one or more process parameters of the crystal growth process may be adjusted in real time. As an example, the model may produce a predicted crystal growth height and/or growth rate during a specified moment in time during a crystal growth process. Based on the duration of the crystal growth process, the predicted crystal growth height may be too tall and may lead to a lower quality crystal if the current growth rate is maintained. Accordingly, one or more process parameters may be adjusted to lower the growth rate and ensure a higher quality final crystal.

In some embodiments, a machine-learning model for predicting in situ parameters may use the ex situ parameters (e.g., operation parameters) from a crystal growth system to generate the predicted in situ parameters (e.g., predicted crystal parameters such as height, mass, shape, growth rate, doping, crystal stress, one or more optical properties, uniformity, etc.). For instance, one or more operation parameters, such as heating element temperature data and/or power consumption data, may be provided to a machine-learning model to obtain predicted crystal parameters, such as height, mass, shape, growth rate, doping, crystal stress, one or more optical properties, uniformity, etc. The machine-learning model may include a variety of characteristics to facilitate generating predicted crystal parameters. For instance, the machine-learning model may be a physics-informed machine-learning model and/or may comprise one or more neural networks.

Additionally, the machine-learning model may be trained on various data sets. For instance, the machine-learning model may be trained using ex situ data (e.g., operation parameter data) associated with one or more crystal growth systems. In some embodiments, determining the predicted crystal parameter(s) may include thermal leak modeling of a crystal growth system. For instance, the machine-learning model may determine the predicted crystal parameters based at least in part on thermal leak modeling of a crystal growth system. In some embodiments, a machine-learned model may be utilized to determine optimal operation parameters (e.g., process parameter(s) controllable outside of the immediate processing environment) to be adjusted and how much to adjust each operation parameter. In some embodiments, a machine-learned model may be utilized to determine optimal process parameters to be adjusted and how much to adjust each process parameter.

In addition, example aspects of the present disclosure provide systems and methods for training machine-learning models to generate one or more in situ parameters. Specifically, example aspects of the present disclosure are directed toward obtaining ex situ data (e.g., operation parameters) associated with the operation of a crystal growth system and training a machine-learning model to predict various in situ parameters (e.g., crystal parameters such as height, mass, shape, growth rate, doping, crystal stress, one or more optical properties, uniformity, etc.). The machine-learning model, once trained, may be used during crystal growth processes to monitor in situ parameters such as crystal parameters and adjust various process parameters (e.g., one or more of temperature, pressure, coolant flow rate, flux, growth segment time duration, heater position, crucible position, or crucible position relative to heater position, insulation position, crystal position, source position, or rotation of the crystal, or any operation parameter controllable outside of the immediate processing environment) associated with the crystal growth process. The machine-learning model may include various characteristics. For instance, in some embodiments, the machine-learning model may be a physics-informed machine-learning model. Additionally, or alternatively, the machine-learning model may comprise one or more neural networks, layers, etc.

For instance, in some embodiments, the one or more neural networks of the machine-learning model may be trained to predict an in situ parameter (e.g., crystal parameter). Based on the predicted in situ parameter (e.g., crystal growth rate, a predicted crystal height, etc.), one or more process parameters of the crystal growth process may be adjusted in real time for instance, to improve final crystal quality and consistency.

Various data associated with a crystal growth system may be obtained to train the machine-learning model. For instance, in some embodiments, operation parameters (e.g., process parameters controllable outside of the immediate processing environment) associated with the crystal growth system may be utilized as training data for the machine-learning model. Additionally, or alternatively, multiple kinds of data may be utilized to train the machine-learning model. In some embodiments, the various data associated with the crystal growth system may be obtained from a plurality of crystal growth systems. In this manner, data may be aggregated from a large pool of different crystal growth systems to train the machine-learning model.

In some embodiments, effectively training the machine-learning model may require various intermediary steps between obtaining data associated with a crystal growth system and training the machine-learning model. For instance, in some embodiments, a correlation between the ex situ data (e.g., operation parameters) from the crystal growth system and the in situ parameters (e.g., crystal parameters) during a crystal growth process may be generated. The correlation may identify a causal relationship or link between the ex situ data (e.g., operation parameters) obtained from the crystal growth system and the in situ parameters (e.g., crystal parameters) during a crystal growth process. Additionally, in some embodiments, the correlation may be used to create a training data set for training the machine-learning model. In these embodiments, the training data set may be based on the ex situ data (e.g., operation parameters) associated with the crystal growth system, or, in some instances, the plurality of crystal growth systems, and/or the correlation between the ex situ data and the in situ data (e.g., crystal parameters, such as crystal height).

In some embodiments, a crystal growth process may include a plurality of crystal growth segments. Each crystal growth segment may be a period of time during which an ex situ parameter (e.g., operation parameters) is obtained, an in situ parameter (e.g., crystal parameters) is estimated, and a process parameter is adjusted according to examples of the present disclosure. A crystal growth process may have any number of crystal growth segments at any level of resolution. Individual crystal growth segments may have the same duration or different durations. The duration of a crystal growth segment may be a process parameter that is adjusted according to examples of the present disclosure.

Example of the present disclosure have many different applications. For instance, in some examples, ex situ parameters such as heater element temperature and/or heater element power consumption may be used to predict or estimate in situ parameters such as crystal growth height or crystal growth rate in real time during a crystal growth process. In some examples, an ex situ parameter such as mass flow rate of species (e.g., as determined by, for instance, a flow rate or control parameter), may be used to predict or estimate dopant levels, optical properties, or other parameters of the crystalline material in real time during a crystal growth process.

Example aspects of the present disclosure can provide a number of technical effects and benefits, including improvements to computing technology, semiconductor growth technology, and/or semiconductor crystalline material growth processes. For instance, the use of ex situ data associated with a crystal growth system to monitor crystal growth parameters reduces the significantly high cost associated with various imaging techniques suitable for the extreme conditions of crystal growth processes, such as x-ray tomography imaging. Additionally, aspects of the present disclosure are directed to reducing semiconductor crystal shape and height variation, thus improving general crystal quality and yield. With more consistency (e.g., less variation) in crystal shape and height, less material is wasted through scrapping during the crystal growth process. As an added result, more usable product may be generated from the same amount of starting material. Additionally, example aspects of the present disclosure may be directed toward crystal growth system maintenance and error reduction. For instance, in monitoring crystal using predicted crystal parameters, drastic variations between the predicted growth parameters and actual yield may enable earlier detection of potential miscalibrations or faults within crystal growth systems and related sensors. In turn, this can reduce the amount of material wasted due to scrap from poorly calibrated or defective machinery.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “center portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, n type material has a majority equilibrium concentration of negatively charged electrons, while p type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, typical embodiments are described and, although specific terms are employed, they are used in a generic and descriptive sense only and not for purposes of limitation of the scope set forth in the following claims.

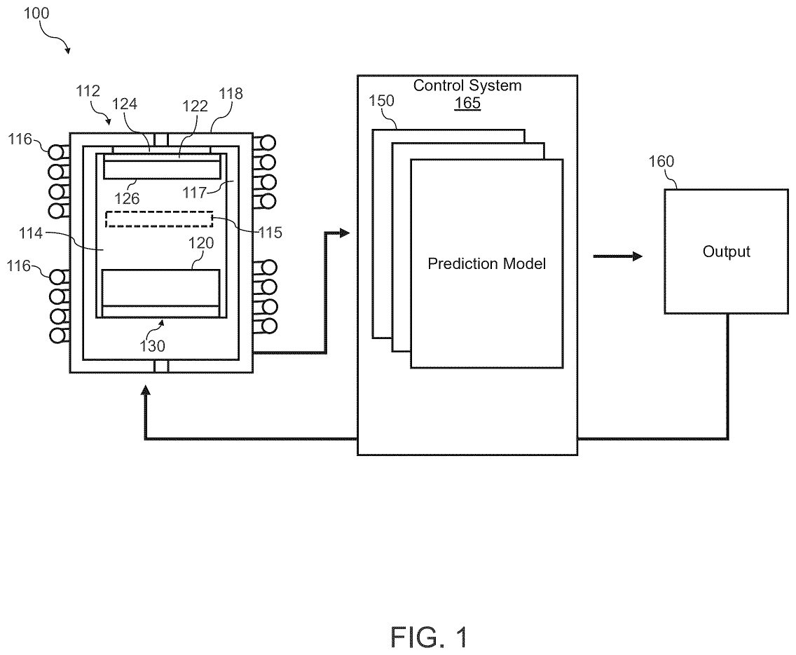

FIG. 1 depicts a system 100 for real-time monitoring of crystal growth processes according to example aspects of the present disclosure. Aspects of the system 100 are directed to adjusting one or more process parameters (e.g., one or more of temperature, pressure, coolant flow rate, flux, growth segment time duration, heater position, crucible position, or crucible position relative to heater position, insulation position, crystal position, source position, or rotation of the crystal, or any operation parameter controllable outside of the immediate processing environment) of the crystal growth process being monitored. The system 100 includes the crystal growth system 112, prediction model 150, and output 160. The crystal growth system 112 includes a crucible 118 defining a crystal growth chamber 114. Insulation 117 (e.g., graphite insulation) may be in the crystal growth chamber 114. The crystal growth system 112 may include one or more heating elements 116 (e.g., induction coils, resistive heating elements) around the crucible 118 and growth chamber 114. The heating elements 116 may impart thermal gradients within the crystal growth chamber 114 to cause vapor transport from a silicon carbide source material 120 to a seed crystal to grow crystalline material on a seed crystal to form a crystalline material 126 (e.g., in a PVT process). The crystal growth chamber 114 may include a seed holder 124 and a source material holder 130. In some embodiments, the source material holder 130 may include the source material 120 to grow a crystal material boule 126 (e.g., crystalline material). The seed holder 124 may include the seed crystal. The source material 120 may include a powdered source material, solid source material, or any other suitable silicon, carbon, and/or silicon carbide source material for growing a silicon carbide crystalline material on the seed crystal. Example silicon carbide source materials are disclosed in U.S. application Ser. No. 18/963,103, filed on Nov. 27, 2024 and in U.S. application Ser. No. 18/963,117,, filed on Nov. 27, 2024, both of which are incorporated herein by reference.

For instance, in some examples, the silicon carbide source material includes a shaped solid silicon carbide source material structure. In some embodiments, the structure may have a composite shape. As used herein, “composite shape” and “composite shaped” refer to any three-dimensional object or component that deviates from a regular cylindrical shape, or a composite solid structure containing multiple shaped solids which may have simple or complex shapes. Deviations from a cylindrical shape include forms with regular or irregular geometries that do not conform to the typical circular or elliptical cross-section of a cylinder. Such structures may exhibit various shapes, including but not limited to structures with polygonal cross-sections; irregularly curved structures; and shapes with holes, voids, surface variations, or combinations thereof. The term also includes shapes containing multiple interconnected or distinct substructures. The substructures may themselves be composite shaped or may be cylindrically shaped. The term encompasses a wide range of geometric configurations and excludes objects that maintain a uniform cylindrical profile throughout their entire volume.

As used herein, “shaped solid” and “solid structure” refer to non-powdered solid components. A non-powdered component, for example, can have a size in at least one dimension of about 1 μm or greater, such as about 10 μm or greater, such as about 50 μm or greater, such as about 100 μm or greater, such as about 200 μm or greater, such as about 1000 μm or greater, such as about 1700 μm or greater, such as about 5 mm or greater, such as about 10 mm or greater. In some example embodiments, a shaped solid or solid structure may be formed by binding powdered particles together to form a composite material. Shaped solids may be shaped in an intentional manner to influence relevant properties, such as sublimation rate, vapor flow paths, thermal gradients, etc. Shaped solids may have one or more shape modifications. Shape modifications are intentional modifications to a source structure to influence relevant properties, such as sublimation rate, vapor flow paths, thermal gradients, etc.

In some embodiments, a composite shaped structure may include complex geometry including shapes, features, symmetry, asymmetry, dimensions, thicknesses, and/or appendages to improve such parameters. In some embodiments, the shaped solid source material may have features that provide desired thermal gradients within the source material. In some embodiments, the shaped solid source material may have features that provide high surface area for better sublimation rates. In some embodiments, the shaped solid source material may have features that provide desired gas flow paths through the source material to efficiently transport the sublimated SiC. In some embodiments, the shaped solid source material may have features that are tailored based on known local variations (e.g., temperature variations) within the crucible. In some embodiments, the shaped solid source material may have features that allow for directional control of the gas flow or heat flow within the source. In some embodiments, the shaped solid source material may have features that allow for control of the sublimation rate over time. Such features are described in more detail below with reference to the drawings.

The source material can be intentionally shaped to control the sublimation rate over time and thus during various stages of crystal growth. The source material can also be shaped to obtain a desired vapor flow/local vapor pressure relative to the seed/growing crystal surface.

In some embodiments, the silicon carbide source material structure may contain multiple layers varying in at least one property. For example, it may include an outer layer and an inner layer such that when used in a sublimation process, the outer layer sublimates first, followed by the inner layer. Varying the properties of the layers can affect the sublimation properties (e.g., rate, temperature required) and crystal growth properties (e.g., polytype, dopant concentration, defect concentration, shape, growth rate).

In some embodiments, the silicon carbide source material structure includes a dopant. The inclusion of a dopant in the source material provides a method for incorporating the dopant into the silicon carbide crystal. This is particularly useful for incorporating dopants which are not easily incorporated using a vapor source.

In some examples, the crystal growth system 112 may include an optional interface structure 115, represented in dashed lines, between the crystalline material 126 and the source material 120. In some examples, the interface structure 115 may include a baffle structure and/or secondary source. Example baffle structures that may be used are disclosed in U.S. patent application Ser. No. 18/962,454, filed on Nov. 27, 2024 which is incorporated herein by reference.

For instance, in some examples, the baffle structure includes a porous material, such as porous graphite. In some examples, at least a portion of the baffle structure has a porosity of greater than about 50% by volume, such as greater than about 70% by volume, such as greater than 80% by volume. Porosity by volume expressed as a percentage refers to the percentage of the volume of voids in the baffle relative to the total volume of the material. In some embodiments, the baffle has a porosity in a range of about 50% to about 97%, such as about 80% to about 97%, such as about 85% to about 97%.

In some embodiments, the baffle structure includes one or more apertures defined through a thickness of the baffle. As used herein, an “aperture” is a defined opening, space, perforation, hole, or void in a structure that extends from one exterior surface of a structure to another exterior surface of the structure. In some embodiments, the baffle has a long dimension that is generally non-perpendicular to the growth surface of the seed crystal. In some examples, the one or more apertures include a plurality of holes defined through the baffle. In some examples, the one or more apertures include an annular aperture defined through a thickness of the baffle. In some examples, a vapor transport direction through the one or more apertures is in a non-perpendicular direction relative to the growth surface of the seed crystal.

In some examples, the one or more apertures are arranged in the baffle to provide for non-uniform vapor transport from the source material to the seed crystal. In some examples, the one or more apertures are arranged in the baffle to provide for asymmetric vapor transport from the source material to the seed crystal. In some examples, the one or more apertures include a first aperture and a second aperture, wherein a width of the first aperture is different from a width of the second aperture. In some examples, the one or more apertures include a first plurality of apertures and a second plurality of apertures, wherein a density of the first plurality of apertures in the baffle is different from a density of the second plurality of apertures in the baffle.

In some examples, the baffle includes a plurality of dividers arranged in a non-perpendicular direction relative to the growth surface of the seed crystal. In some examples, the one or more apertures are arranged to direct vapor in a direction that is more towards a center of the seed crystal relative to a peripheral portion of the seed crystal. In some examples, the one or more apertures are arranged to direct vapor in a direction that is more towards a peripheral portion of the seed crystal relative to a central portion of the seed crystal.

In some examples, the baffle includes a plurality of baffle structures (e.g., baffle plates). In some examples, the baffle includes a first baffle plate having the one or more apertures and a second baffle plate with no apertures. In some examples, the baffle includes a first baffle plate comprising a first aperture and a second baffle plate comprising a second aperture. In some examples, the first aperture is aligned with the second aperture. In some examples, the first aperture is not aligned with the second aperture.

In some examples, one or more portions of the baffle element, coating, surface or subsurface treatment for the baffle or any of its parts may include an engineered structure having a construction or configuration that is or includes one or more of a porous structure, woven wire, perforated plate, foam, screen printed material, refractory metal, 3D printed structure, coated wire, carbon fiber mesh, carbon wires, refractory metal wires, woven mesh, cast component(s), grid, sintered powder, composite laminate, electroformed structure, braided wire, honeycomb structure, felt structure, nanostructured film, carbon nanotubes, tightly or loosely interconnected network of structures or other suitable construction or configuration. Portions or the entirety of any of the foregoing may be coated, treated and/or converted to form a metal carbide surface, subsurface or entire article of metal carbide. One or more combinations of any of these constructions or configurations may be used without deviating from the scope of the present disclosure. For example, in some embodiments, a first baffle structure (e.g., a first baffle plate) may include a first configuration (e.g., porous material) and a second baffle structure (e.g., a second baffle plate) may include a second configuration (e.g., honeycomb structure). In some examples, the baffle structure may be a secondary source or may comprise a secondary source, such as a secondary carbon source (e.g., if the interface structure comprises graphite).

The interface structure 115 may have one or more apertures or may be made from a porous material to allow for the passage of vapor. In some examples, the interface structure 115 may be a graphite material (e.g., porous graphite, such as porous graphite having a porosity greater than about 40%, such as greater than about 70%, such as about 40% to about 97%, such as about 70% to about 97%). In some examples, the interface structure 115 may be a coated graphite material. Example coatings that may be used are disclosed in U.S. application Ser. No. 18/963,196, filed on Nov. 27, 2024, U.S. application Ser. No. 18/963,136, filed on Nov. 27, 2024, and U.S. application Ser. No. 18/963,240, filed on Nov. 27, 2024, which are incorporated herein by reference.

In some embodiments, a coating may include metal particles and a binder that forms a matrix holding the particles together in a coating. In some embodiments, the metal may be tantalum. In some embodiments, the metal particles may be less than 10 microns in diameter. In some embodiments, the binder may be a thermally curable resin. In some embodiments, the metal particles may be functionalized with compounds that promote particle dispersion in the coating and may couple to the binder. In some embodiments, the coating is stable in air, forms a stable suspension, and can be used to dip-coat or paint parts. In some embodiments, solvent may be added to the coating, for example to tune the viscosity of the coating, tune the metal particle concentration, or tune the coating uniformity. In some embodiments, a compound that promotes sintering may be added to the coating mixture to promote sintering of the particles (e.g., at temperatures above 1000° C.). The thickness of the final coating may be able to be controlled, for example by varying the concentration of metal particles in the coating and by varying the deposition volume of the coating onto the surface or part.

In some embodiments, a coating be created by applying an organometallic compound to at least one surface of a structure, wherein the at least one surface of the structure contains carbon or an oxide, curing the organometallic compound on the at least one surface of the structure; and heating the organometallic compound on the at least one surface of the structure such that the metal carbide coating is formed on the at least one surface of the structure, wherein the organometallic compound includes a central metal atom; and ligands capable of forming polydentate bonds to the central metal atom.

In some embodiments, the central metal atom is selected from the group consisting of chromium, hafnium, iridium, molybdenum, niobium, osmium, rhenium, rhodium, ruthenium, tantalum, titanium, tungsten, vanadium, zirconium, or a mixture thereof. In some embodiments, the central metal atom is tantalum. In some embodiments, the ligands capable of forming polydentate bonds to the central metal atom are polar. In some embodiments, the ligands capable of forming polydentate bonds to the central metal atom are selected from the group consisting of alkyl amines, alkyl acetates, alkyl alcohols, alkyl glycols, alkyl diols, alkyl nitrites, alkyl halides, alkyl aromatics, alkylated charge transfer donor-acceptor pairs, or a mixture thereof.

In some examples, furanic ultra high temperatures adhesives (UHTAs) may be used as a binder in a paint that converts to a coating, such as solution processable ceramic coatings (e.g., TaC, NbC, SiC, etc.) or a non-ceramic coating (e.g., glassy carbon coatings). Certain furan functionalized compound can be used as ultra-high temperature adhesives. The chemistry of furan rings allows a broad range of furan-containing polymeric, molecular, or inorganic-organic hybrid materials that can function as UHTAs. Examples of such materials incorporating the furan heterocycle as a structural unit include: furanic polymers and resins; furanic molecules and macromolecules; furanic rigid network solids; and furan functionalized micromaterials or nanomaterials.

With the proper material design, the furanic constituents would allow these compounds to participate in crosslinking (curing) through Diels-Alder cycloaddition and the formation of a bonded glassy carbon (BGC) network. Crosslinking, which forms a three-dimensional polymeric network, can be initiated through the application of chemical, photochemical, thermal, mechanical, or electrical energy. Once cured, these materials become structurally robust solids that bind strongly to a substrate. As these cured solids are pyrolized, the furan constituents undergo ring opening and forming reactive alkene fragments (CH2═CH2) and radicals which drive the formation of and condensation of polyaromatic cores resulting in a BGC network, which results in an UHTA.

The adhesion of furanic UHTAs may be further improved through the incorporation of a filler material. Use of such filler materials with UHTAs as a binding agent may be referred to as a “brick and mortar” model. Such filler materials may improve the adhesive properties of the UHTA by mechanical reinforcement. During pyrolysis of the furanic UHTA, the filler or any products generated by the chemical change of the filler may be incorporated into the network as a structural unit and mechanically strengthen the resulting bonded glassy carbon network through covalent bonding and/or strong non-covalent interactions. Such filler materials may also improve the adhesive properties of the UHTA by promoting carbon condensation. During pyrolysis of the furanic UHTA, the filler or any products generated by the chemical change of the filler may aid in the condensation of intermediate polyaromatic cores through covalent bonding and/or strong non-covalent interactions. By contributing to the condensation, a denser bonded glassy carbon network may be produced.

In some embodiments, filler materials used with furanic UHTAs may be active or may be passive. Active fillers undergo a chemical change (e.g., thermal decomposition, reduction, oxidation, solid state synthesis, etc.) into one or more products during the pyrolysis of the UHTA. Active fillers may also change aggregate state or are subject to diffusion before or during undergoing a chemical change. Passive fillers can form covalent bonds or participate in strong non-covalent interactions with the bonded glassy carbon network, but do not undergo further chemical reactions during the pyrolysis of the UHTA. Passive fillers can be impermeable or can be porous, allowing the furanic UHTA to penetrate into the material. In the case of a porous filler, the bonded glassy carbon network may form inside and outside the filler material during the pyrolysis of the UHTA. Passive fillers may participate in sintering, recrystallization, surface or bulk diffusion processes during temperature exposure. Either active or passive fillers may also create voids or porosity during temperature treatments. For example, fillers may decompose or evaporate to create voids in the UHTA.

The interface structure 115 may extend all the way across a width or diameter of the growth chamber and/or all the way across the flux path. The interface structure 115 may be included in any of the crystal growth systems provided herein without deviating from the scope of the present disclosure.

In some examples, the crystal growth system 112 may include one or more actuators. The actuators may be configured to impart translational and/or rotational movement to one or more components of the crystal growth system 112, such as the seed holder 124 and crystalline material 126, the source material 120, the insulation 117, the heating elements 116, the interface structure 115, the crucible 118, and/or other elements. The actuator(s) may be include any suitable type of actuator, such as an electric actuator (e.g., servo motor, stepper motor, linear motor, DC motor, AC motor, rotary motor), piezoelectric actuator, pneumatic actuator (e.g., pneumatic cylinder, pneumatic diaphragm), hydraulic actuator (e.g., hydraulic cylinder), electromagnetic actuator (e.g., solenoid), thermal actuator (e.g., shape memory alloy actuator, bimetallic actuator), vacuum actuator (e.g., vacuum suction actuator) and/or other suitable actuator, rotary actuator (e.g., screwing arrangement). The actuator(s) may be operate independently of each other to cause relative positioning of components relative to other components. For instance, in some embodiments, the source 120 may be rotated independently of the crystalline material 126. In some embodiments, one or more actuators may be operable to move the crystalline material 126 (e.g., the growth face of the crystalline material 126) to different vertical positions relative to the source material 120 during a crystal growth process. For instance, one or more actuators may move the crystalline material 126 and/or the source material 120 such that there is a first transport distance between the crystalline material 126 and the source material 120 for a first process period. One or more actuators may move the crystalline material 126 and/or the source material 120 such that there is a second transport distance (e.g., different from the first transport distance) between the crystalline material 126 and the source material 120 for a second process period. Those of ordinary skill in the art, using the disclosure provided herein, will understand that any type of actuator may be used to move components without deviating from the scope of the present disclosure.

Various ex situ parameters (e.g., operation parameters) may be obtained from the crystal growth system 112 and provided to the prediction model 150. The prediction model 150 may be implemented and/or stored on a computing device that may include or may be a part of, for instance, a controller or control system 165 for controlling aspects of the crystal growth system. For instance, various measurement devices or control tools (e.g., control settings) may be used to obtain the ex situ parameters (e.g., operation parameters). The ex situ parameters may be, for instance, temperature of one or more components of the crystal growth system (e.g., heater temperature, crucible temperature, insulation temperature), power consumption of the heaters, chemical composition of species entering the chamber, mass flow of species entering the chamber, coolant temperature, coolant flow rate, insulation displacement, pressure changes in the crystal growth system, or other suitable measurable or controllable parameters associated with operation of the crystal growth system, for instance, during a crystal growth process. Further, in some embodiments, various combinations of ex situ parameters (e.g., operation parameters) may be obtained from the crystal growth system 112.

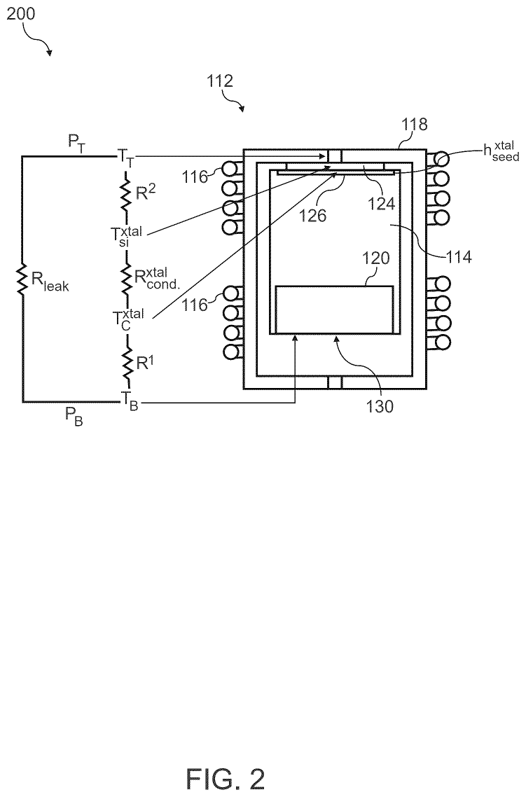

In some embodiments, the ex situ parameters (e.g., operation parameters) obtained from the crystal growth system 112 may be provided to the prediction model 150 to generate the output 160. For instance, one or more operation parameters, such as power consumption data or heating element temperature data, may be obtained from the crystal growth system 112 during a crystal growth process and provided to the prediction model 150 which, in turn, may determine one or more predicted in situ parameters (e.g., crystal parameters) as the output 160 during a crystal growth process. The prediction model 150 may include a variety of properties to facilitate such determinations. For instance, in some embodiments, the prediction model 150 may be a physics based model and may utilize various physics mechanics and algorithms to determine the predicted crystal parameters (such modeling will be discussed in greater detail with reference to FIG. 2). Additionally, in some embodiments, the prediction model 150 may include one or more neural networks and/or may be a physics informed machine-learning model.

To determine predicated in situ parameters (e.g., crystal parameters), the prediction model 150 may be trained on various data sets. For instance, in some embodiments, the prediction model 150 may be trained on ex situ data (e.g., operation parameter data), such as heating element temperature data, heating element power consumption data and/or other ex situ data.

As previously discussed, the output 160 may include one or more predicted in situ parameters (e.g., crystal parameters). In some embodiments, the predicted in situ parameters may include a predicted growth height and/or growth rate of a crystalline material (e.g., semiconductor crystal) associated with the crystal growth process. Other suitable in situ parameters (e.g., crystal parameters) may be predicted using the model 150 without deviating from the scope of the present disclosure. For instance, in situ parameters (e.g., crystal parameters) may include crystal shape, mass, doping level, width, crystal stress, etc. may be predicted using the model 150.

In some embodiments, the output 160 may be used by the control system 165 to adjust one or more process parameters of a crystal growth process within the crystal growth system 112. The control system 165 may include one or more control devices that are able to control components of the crystal growth system 112 to implement the adjustment to the one or more process parameters.

For instance, as an example, the prediction model 150 may obtain ex situ parameters (e.g., operation parameters) from the crystal growth system 112 during a crystal growth process and determine the output 160. The output 160 may be used to determine an in situ parameter (e.g., crystal parameters) during the crystal growth process. The in situ parameter (e.g., crystal parameters) may be used to adjust one or more process parameters associated with the crystal growth system 112. Example process parameters include temperature, pressure, coolant flow rate, flux, growth segment time duration, heater position, crucible position, crucible position relative to heater position, crystal position, source position, rotation of the crystal, and/or any of the controllable operation parameters provided herein (e.g., heater element temperature, heater element power consumption, mass flow rate of species into the chamber, etc.). The process parameter can be any controllable process variable or combination of process variables used to affect a crystal growth process. In some embodiments, a machine-learning model and related circuitry may be utilized to determine optimal process parameters to be adjusted and how much to adjust each process parameter.

FIG. 2 depicts a cross-sectional schematic diagram 200 of an example crystal growth system 112 for use in a crystal growth process according to example aspects of the present disclosure. The reference elements of the example crystal growth system 112, as discussed with reference to FIG. 1, shall be incorporated in the discussion of FIG. 2 herein.

In some embodiments, the prediction model 150 depicted in FIG. 1 may be a physics-informed machine-learning model, for instance, based on thermal leak modeling of the crystal growth system 112. Thermal leak modeling allows for a quantification of the innate power and heating properties of a crystal growth system, such as the crystal growth system 112. Such innate properties may vary from system to system and can affect the growth rate of a crystal within the system. Therefore, incorporating thermal leak modeling into the prediction model 150 may provide for more accurate predictions as thermal leak may directly impact the height of a crystal during a crystal growth process.

Thermal leak modeling may model various parameters related to the crystal growth system 112, including, but not limited to, the plurality of heating elements 116, the crystalline material 126, the source material holder 130, and the seed holder 124. As depicted in FIG. 2, R¹ and R² may be resistances associated with a first and second set of the plurality of heating elements 116. R^{xtal} cond may be a resistance associated with the crystalline material 126. R^{xtal}_{cond} may be indicative of the height of the crystal material 126 and the height of the seed crystal, h^{seed}ₓₜₐₗ. The resistances R¹, R², and R^{xtal}_{cond} may be modeled in series with the thermal leak of the crystal growth system 112, Rₗₑₐₖ in parallel with the other resistors. In addition to needing resistances of the system components, determining Rₗₑₐₖ and Rₗₑₐₖ over time (e.g., quantification of a growth system's thermal leak and thermal leak throughout a crystal growth process) may require various power measurements and temperature measurements. For instance, in some embodiments, the model may account for temperature at the top of the crystal growth chamber 114, temperature at the bottom of the crystal growth chamber 114, temperature of the silicon face of crystalline material 126, temperature of the carbon face of crystalline material 126, each depicted as T_{T}, T_{B}, T^{xtal}ₛᵢ, and T^{xtal}_{c} respectively. In some embodiments, the model accounts for power consumption associated with the crystal growth system 112. For instance, the power from the top portion of the heating elements, represented as P_{T}, and the power from the bottom portion of the heating elements P_{B}, may be used to accurately model the thermal leak of the crystal growth system 112. Accordingly, in some embodiments, the prediction model 150 may be a physics-informed machine-learning model which may perform thermal leak modeling of the crystal growth system 112 based on the thermal leak modeling discussed with reference to FIG. 2.

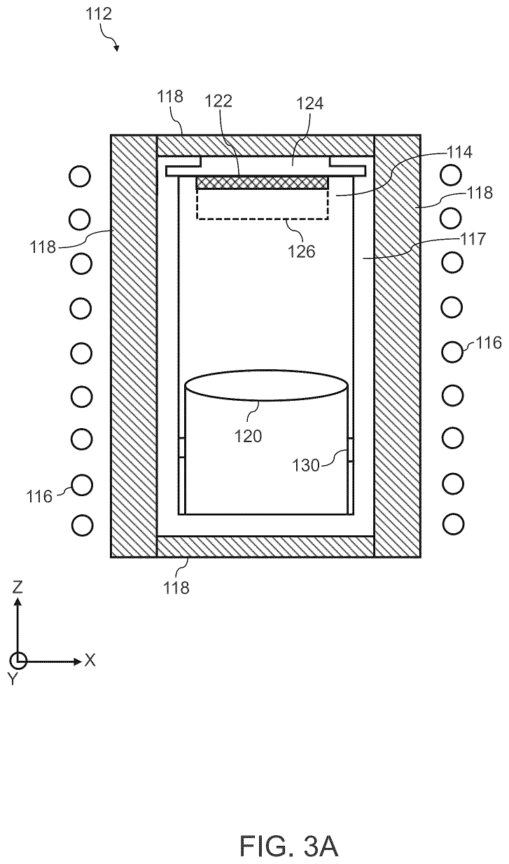

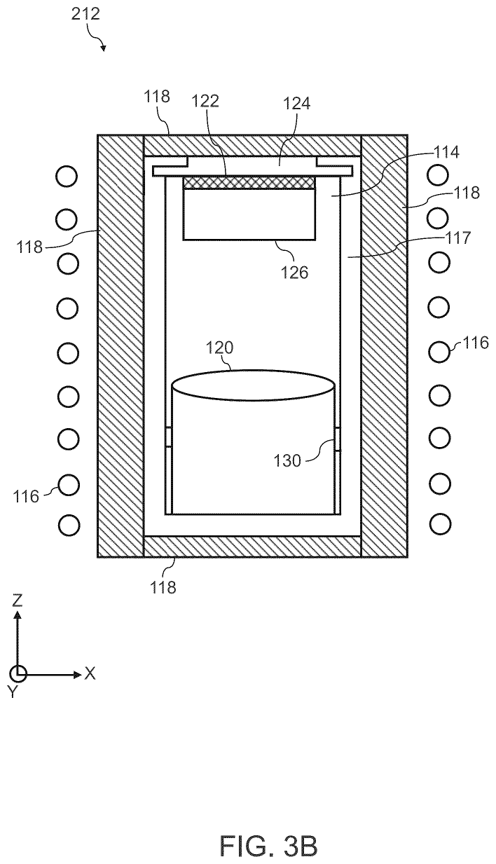

FIGS. 3A and 3B depict a cross-sectional schematic diagram of an example crystal growth system 112 during various crystal growth segments of a crystal growth process according to example aspects of the present disclosure. Referring to FIG. 3A, the crystal growth system 112 may be used to conduct a crystal growth process. During such process, a crystalline material 126 (e.g., crystalline material boule) may be grown on the seed material 122 held by the seed holder 124. The crystal growth system 112 includes many of the components (e.g., crucible 118, seed holder 124, source material 120) described in detail with reference to FIG. 1.

As discussed with reference to FIG. 1, in some embodiments, data indicative of one or more ex situ parameters (e.g., operation parameters) of the crystal growth system 112 may be obtained (e.g., in real time) during a crystal growth process. In some embodiments, the crystal growth process may include a plurality of growth segments. Each growth segment can be associated with a specific process recipe (e.g., temperature, pressure, time duration, crucible position, heater position, heater position relative to crucible position, coolant flow rate, etc.) for a process period.

FIG. 3A depicts the growth of the crystal material boule 126 during a first growth segment. One or more ex situ parameters (e.g., operation parameters) associated with the first growth segment may be obtained to predict or estimate an in situ parameter in real time, such as a crystal parameter, such as growth rate, growth height, or other crystal parameter of the crystalline material 126. Based on the predicted or estimated in situ parameter, one or more process parameters associated with the crystal growth system 112 may be adjusted. As examples, future segment time duration, temperature, pressure, flux, coolant flow rate, crucible position, heater position, heater position relative to crucible position, crystal position, or other parameters may be adjusted in future growth segments.

Referring now to FIG. 3B, the crystal growth system 112 is depicted at a later second growth segment of the crystal growth process. One or more ex situ parameters (e.g., operation parameters) associated with the second growth segment may be obtained to predict a in situ parameter (e.g., crystal parameter such as, for example, growth rate or growth height) of the crystal material 126. Based on the predicted crystal parameter, one or more process parameters associated with the crystal growth system 112 may be adjusted. As depicted, the actual height of the crystalline material 126 has changed, the ex situ parameters (e.g., operation parameters) may result in different estimations of in situ parameters (e.g., crystal parameters), leading to different adjustments to the process parameters of the crystal growth system 112, compared to those from the first growth segment depicted in FIG. 3A.

Example aspects of the present disclosure are additionally directed to training machine-learning models to predict certain in situ parameters, such as crystal parameters, according to examples of the present disclosure. In some embodiments, the training process may include obtaining ex situ data (e.g., operation parameters) associated with operation of a crystal growth system during a crystal growth process, and training a machine-learning model to predict an in situ parameter (e.g., a crystal parameter such as, for example, growth height or growth rate of a crystalline material 126) using the ex situ data. For instance, in some embodiments, data from a plurality of crystal growth systems during a plurality of crystal growth processes may be aggregated to train the machine-learning model. The aggregated data may include various ex situ data (e.g., operation parameters). As examples, heating element power consumption data and/or heating element temperature data associated with the crystal grow systems may be used to train the machine-learning model. In some embodiments, the training process may include generating model training data for training the model using in situ data (e.g., crystal parameters) and ex situ data (e.g., operation parameter) associated with a crystal growth process or processes. For instance, a correlation between the ex situ data (e.g., operation parameters) associated with the crystal growth systems and a plurality of heights of a crystalline material from the same crystal growth process (e.g., crystal parameters) may be determined and used as model training data. The model training data may be used to train the machine-learning model to predict in situ parameters, such as crystal parameters, such as, for example, crystal height and/or growth rate during a crystal growth process.

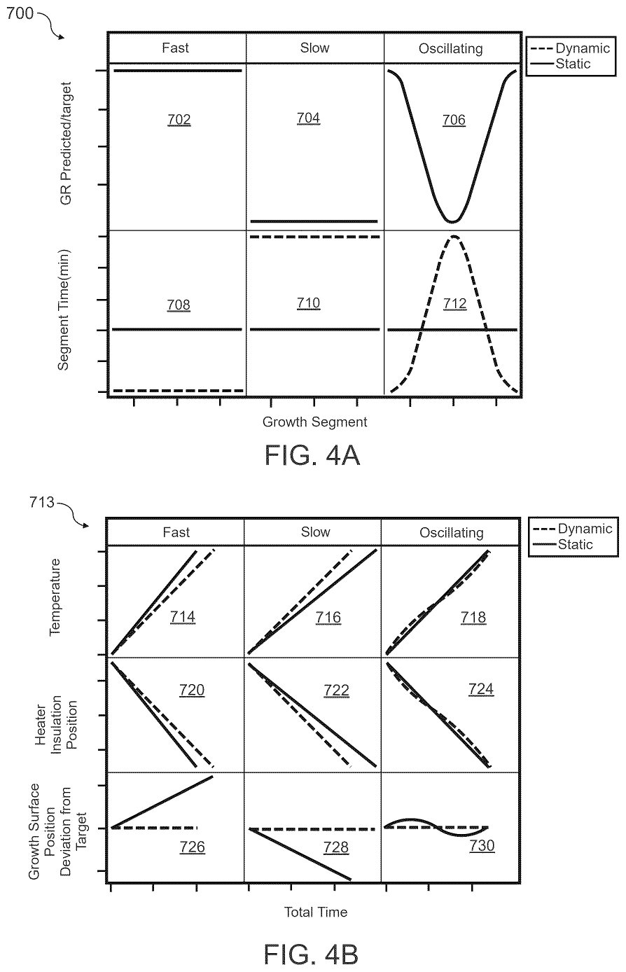

FIGS. 4A-B depicts example crystal growth system control logic diagrams according to example aspects of the present disclosure. FIGS. 4A-B depict example control logic for implementing adjustments to one or more process parameters associated with a crystal growth system and a crystal growth process based on predicted in situ parameters (e.g., crystal parameters). Specifically, example aspects of the present disclosure are depicted throughout FIGS. 4A-B as the dynamic dashed line, whereas traditional growth process techniques are depicted by the static solid line. The control logic depicted in FIGS. 4A-B may be carried out by an example system, such as the system 100 depicted in FIG. 1.

Referring to FIG. 4A, a segment time duration comparison chart 700 is depicted. The segment time duration comparison chart 700 depicts various scenarios where the dynamic segment time duration techniques discussed herein are compared to the traditional static techniques known in the art. As depicted in 708, 710, and 712, the static line remains constant, exhibiting a uniform segment time duration throughout the crystal growth process due to traditional methods not using the predicted and target growth rates shown in 702, 704, and 706. At 702, the system 100 determines a fast growth rate. Accordingly, at 708, the dynamic segment time duration and/or other process parameters are reduced to below the static segment time duration to account for the fast growth rate identified in 702. Similarly, at 704, the system 100 determines a slow growth rate. Accordingly, at 710, the dynamic segment time duration and/or other process parameters are increased above the static segment time duration to account for the slower growth rate identified in 704. At 706, the system 100 identifies an oscillating growth rate. Accordingly, at 712, the dynamic segment time duration and/or other process parameters have changed to an inverse oscillating duration to account for the oscillating growth rate identified in 706. It should be appreciated that the scenarios depicted in FIG. 4A are example generalizations. In practice, infinitely many in situ parameters (e.g., crystal parameters) may be determined by an example system, such as system 100, and the segment time duration and/or other process parameters may be modified to appropriately respond to such determinations in accordance with aspects of the present disclosure.

Referring to FIG. 4B, a temperature and heater/insulation position comparison chart 713 is depicted. The temperature and position comparison chart 713 shows example dynamic adjustments of temperature and heater/insulation position over the entire duration of a crystal growth process associated with a crystal growth system. The adjustments of the example process parameters are depicted alongside an overall position error (i.e., deviation from target growth height) to compare outcomes of traditional static techniques and the dynamic adjustment methods of the present disclosure. The adjustment of example process parameters in accordance with aspects of the present disclosure is depicted by the dynamic dashed line. The traditional techniques are depicted by the static solid line. The two additional process parameters, temperature and heater/insulation position, may each be modified based on a comparison between a predicted growth rate and a target growth rate. Various example comparisons of predicted growth rate and target growth rate are depicted at 702, 704, and 706 in FIG. 4A.

In one example, at 714, in response to a faster than target growth rate (see FIG. 4A at 702), the dynamic adjustment may reduce the rate the temperature increases over time, as compared to the static technique in solid line, to account for the faster growth rate. Similarly, at 720, in response to the faster than target growth rate, the rate of change of the dynamic adjustment may reduce the rate of heater/insulation position adjustment. As a result, at 726, the dynamic technique achieves no position error, whereas the static technique ends up overshooting the intended position.

In one example, at 716, the dynamic temperature increases the rate of change in temperature compared to the static technique in response to a slower than target growth rate being determined. Similarly, at 722, the dynamic heater/insulation position adjustment decreases the rate of change in heater/insulation position compared to the static technique in response to the slower than target growth rate being determined (see FIG. 4A at 704). As a result, at 728, the dynamic position error remains zero, whereas the position undershoots the intended position.

In one example, at 718, the dynamic temperature oscillates compared to the static temperature based on an oscillating growth rate being determined. Similarly, at 724, the dynamic crucible position oscillates compared to the Static technique in response to the oscillating growth rate being determined (see FIG. 4A at 706). As a result, at 730, the dynamic position error remains zero whereas the static position error oscillates.

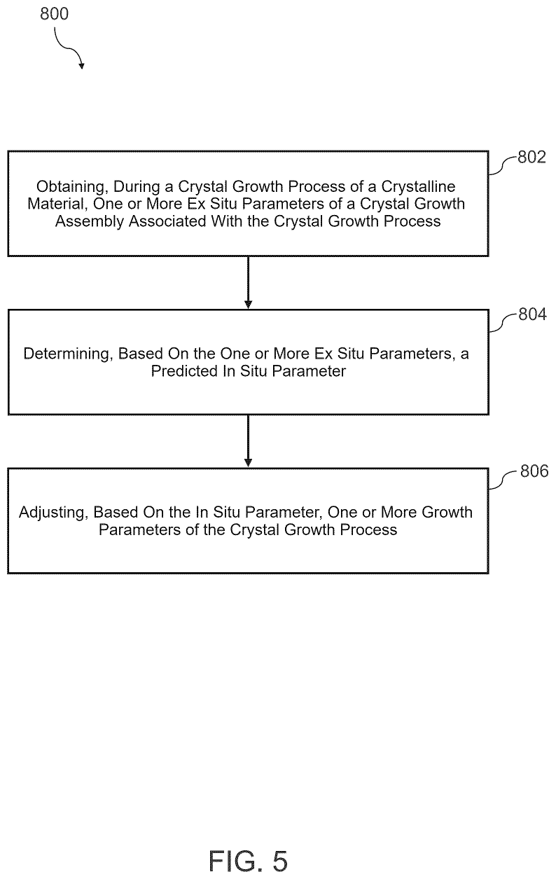

FIG. 5 depicts a block diagram of an example method 800 according to example aspects of the present disclosure. FIG. 5 depicts example process steps for purposes of illustration and discussion. Those having ordinary skill in the art, using the disclosures provided herein, will understand that the process steps of any of the methods described in the present disclosure may be adapted, modified, include steps or operations not illustrated, omitted, and/or rearranged without deviating from the scope of the present disclosure.

At 802, the method 800 includes obtaining, during a crystal growth process of a crystalline material, one or more ex situ parameters (e.g., operation parameters) of a crystal growth system associated with the crystal growth process. The ex situ parameters (e.g., operation parameters) may comprise any of the ex situ parameters discussed herein.

At 804, the method 800 includes determining, based on the one or more ex situ parameters (e.g., operation parameters), a predicted in situ parameter (e.g., crystal parameter). The predicted in situ parameter (e.g., crystal parameter) may be, for example, one or more of a predicted crystal growth rate and/or a predicted crystal growth height. In some embodiments, determining the predicted crystal parameter includes providing the one or more ex situ parameters (e.g., operation parameters) to a machine-learning model for predicting in situ (e.g., crystal parameters) and obtaining the predicted crystal parameter from the model. In some embodiments, the machine-learning model may be a physics-informed machine learning model. Additionally, in some embodiments the machine-learning model may determine a predicted in situ parameter based on thermal leak modeling of the crystal growth system.

At 806, the method 800 includes adjusting, based on the predicted in situ parameter (e.g., crystal parameter), one or more process parameters of the crystal growth process, for instance, in real time or for later crystal growth processes. Process parameters are any parameters that may be controlled during a crystal growth process to affect crystal growth. Example process parameters include temperature, pressure, coolant flow rate, flux, growth segment time duration, heater position, crucible position, crucible position relative to heater position, crystal position, source position, rotation of the crystal, and/or any of the controllable operation parameters provided herein (e.g., heater element temperature, heater element power consumption, mass flow rate of species into the chamber, etc.). The process parameter can be any controllable process variable or combination of process variables used to affect a crystal growth process.

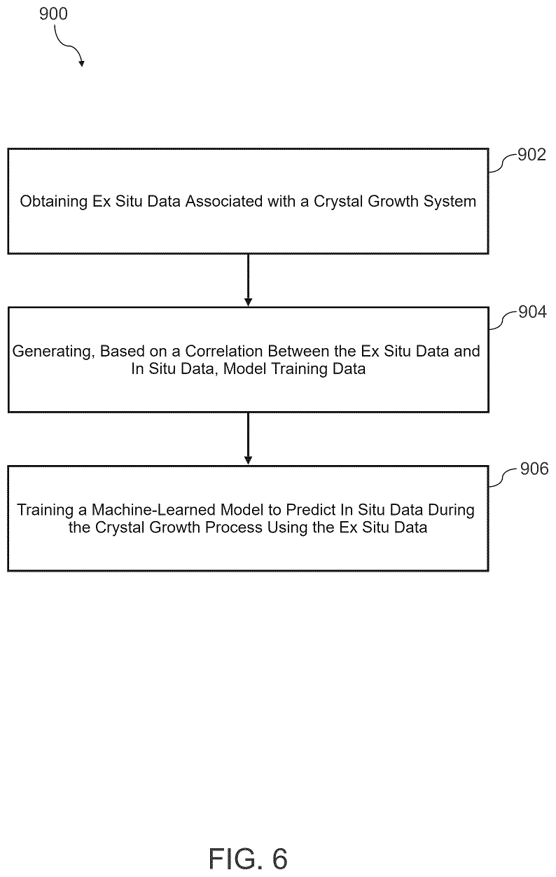

FIG. 6 depicts a block diagram of an example method 900 according to example aspects of the present disclosure. FIG. 6 depicts example process steps for purposes of illustration and discussion. Those having ordinary skill in the art, using the disclosures provided herein, will understand that the process steps of any of the methods described in the present disclosure may be adapted, modified, include steps not illustrated, omitted, and/or rearranged without deviating from the scope of the present disclosure.

At 902, the method 900 includes obtaining ex situ data (e.g., operation parameters) associated with operation of a crystal growth system during a crystal growth process. The ex situ data (e.g., operation parameters) associated with operation of the crystal growth system may include various data streams. For instance, in some embodiments, the ex situ data (e.g., operation parameters) may include power consumption data and, additionally or alternatively, heating element temperature data. In some embodiments, the ex situ data (e.g., operation parameters) associated with operation of the crystal growth system may be obtained from a plurality of crystal growth systems during a plurality of crystal growth processes.

At 904, the method includes generating model training data. In some embodiments, the model training data is generated based on a correlation between data associated with operation of the crystal growth system and a plurality of in situ parameters (e.g., crystal parameters) associated with the crystal growth process.

At 906, the method includes training a machine-learning model to predict in situ parameters (e.g., crystal parameters) during the crystal growth process using the ex situ data (e.g., operation parameter data). In some embodiments, the machine-learning model may be a physics-informed machine-learning model. Additionally, in some embodiments, the machine-learning model may include one or more neural networks.

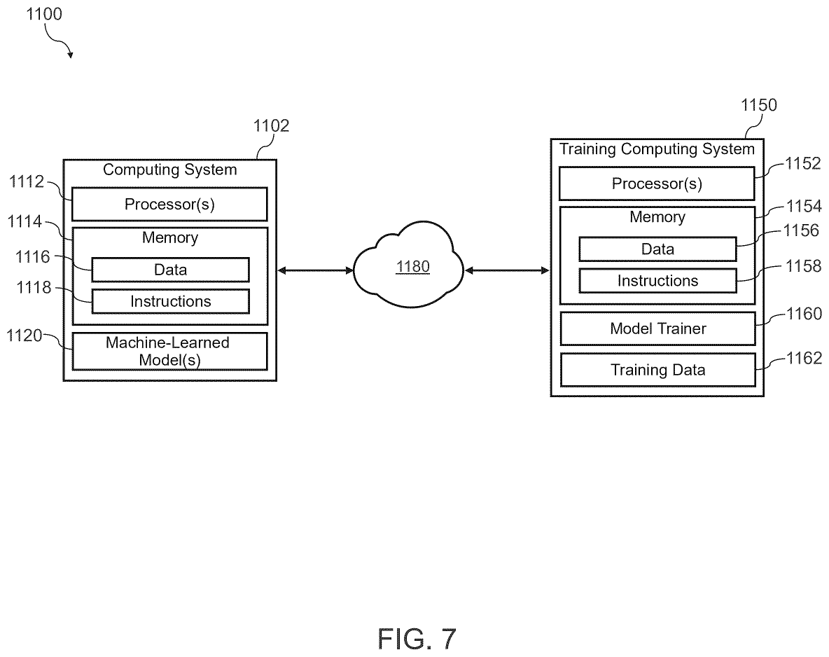

FIG. 7 depicts a block diagram of an example computing system 1100 according to example aspects of the present disclosure. The example computing system 1100 that can be used to implement systems and methods according to example embodiments of the present disclosure. The system 1100 includes a computing system 1102 and a training computing system 1150 that are communicatively coupled over a network 1180.

The computing system 1102 can include any type of computing device (e.g., classical and/or quantum computing device). The computing system 1102 includes one or more processors 1112 and a memory 1114. The one or more processors 1112 can be any suitable processing device (e.g., a processor core, a microprocessor, CPU, GPU, an ASIC, a FPGA, a controller, a microcontroller, etc.) and can be one processor or a plurality of processors that are operatively connected. The memory 1114 can include one or more non-transitory computer-readable storage mediums, such as RAM, ROM, EEPROM, EPROM, flash memory devices, magnetic disks, etc., and combinations thereof. The memory 1114 can store data 1116 (e.g., parameters, input data, etc.) and instructions 1118 which are executed by the processor 1112 to cause the computing system 1102 to perform operations. In some implementations, the computing system 1102 can store or include one or more machine-learning models 1120 (e.g., autoencoders, machine-learning encoding models, etc.) as described herein.

The computing system 1102 can train the machine-learning model(s) 1120 via interaction with the training computing system 1150 that is communicatively coupled over the network 1180. The training computing system 1150 can be separate from the computing system 1102 or can be a portion of the computing system 1102.

The training computing system 1150 includes one or more processors 1152 and a memory 1154. The one or more processors 1152 can be any suitable processing device (e.g., a processor core, a microprocessor, CPU, GPU, an ASIC, a FPGA, a controller, a microcontroller, etc.) and can be one processor or a plurality of processors that are operatively connected. The memory 1154 can include one or more non-transitory computer-readable storage mediums, such as RAM, ROM, EEPROM, EPROM, flash memory devices, magnetic disks, etc., and combinations thereof. The memory 1154 can store data 1156 and instructions 1158 which are executed by the processor 1152 to cause the training computing system 1150 to perform operations. In some implementations, the training computing system 1150 includes or is otherwise implemented by one or more server computing devices.

The training computing system 1150 can include a model trainer 1160 that trains the machine-learning model(s) 1120 using various training or learning techniques, such as, for example, backwards propagation of errors. In some implementations, performing backwards propagation of errors can include performing truncated backpropagation through time. The model trainer 1160 can perform a number of generalization techniques (e.g., weight decays, dropouts, etc.) to improve the generalization capability of the models being trained.

In particular, the model trainer 1160 can train the machine-learning model(s) 1120 based on a set of training data 1162, such as any of the training data described herein.

The model trainer 1160 includes computer logic utilized to provide desired functionality. The model trainer 1160 can be implemented in hardware, firmware, and/or software controlling a general purpose processor. For example, in some implementations, the model trainer 1160 includes program files stored on a storage device, loaded into a memory and executed by one or more processors. In other implementations, the model trainer 1160 includes one or more sets of computer-executable instructions that are stored in a tangible computer-readable storage medium such as RAM hard disk or optical or magnetic media.

The network 1180 can be any type of communications network, such as a local area network (e.g., intranet), wide area network (e.g., Internet), or some combination thereof and can include any number of wired or wireless links. In general, communication over the network 1180 can be carried via any type of wired and/or wireless connection, using a wide variety of communication protocols (e.g., TCP/IP, HTTP, SMTP, FTP), encodings or formats (e.g., HTML, XML), and/or protection schemes (e.g., VPN, secure HTTP, SSL).

FIG. 7 illustrates one example computing system that can be used to implement example aspects of the present disclosure. Other computing systems can be used as well. For example, in some implementations, the computing system 1102 can include the model trainer 1160 and the training data 1162. In such implementations, the model(s) 1120 can be both trained and used locally at the computing system 1102.

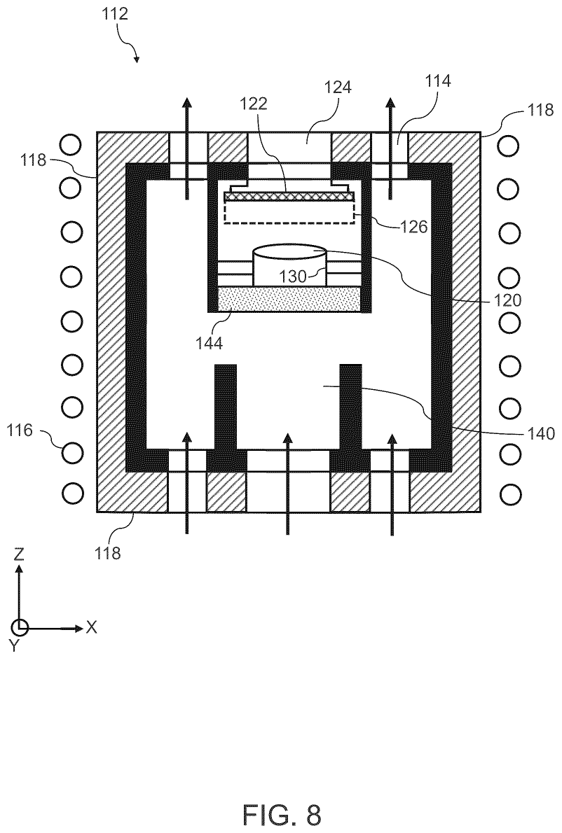

In any of the embodiments described herein, the crystal growth chamber may be implemented in a number of different arrangements or configurations. Thus, while embodiments of the present disclosure may be illustrated with certain crystal growth system designs, the scope of the present disclosure is not limited to such designs but will find application in different crystal growth systems using many different types of reaction crucibles. It should be appreciated that aspects of the present disclosure may be used with any suitable crystal growth system without deviating from the scope of the present disclosure. FIGS. 8A-14B below illustrate example crystal growth system in which the systems and methods of the present disclosure may be implements.

For instance, FIG. 8 depicts an example embodiment of the crystal growth system 112 as a continuous feed PVT system according to example aspects of the present disclosure. In some embodiments, the crystal growth system 112 may be a continuous feed PVT (CF-PVT) system. In the CF-PVT system, the crystal growth chamber 114 may include an upper chamber 138 and a lower chamber 140. The upper chamber 138 may include the solid source material 120 and the seed material 122. The upper chamber 138 may be separated from the lower chamber 140 by a foamed structure 144. The foamed structure 144 may be formed, for example, from a gas-permeable graphite foam. The solid source material 120 may be placed on the foamed structure 144 within the upper chamber. A gaseous silicon source (e.g., trimethylsilane diluted in argon) may be supplied to the lower chamber. As the gaseous silicon source flows through the foamed structure 144, it may react with a carbon source within the foamed structure 144 (e.g., graphite) to form silicon carbide. The CF-PVT system combines the PVT process for the growth of single crystals and high-temperature chemical vapor deposition (HTCVD) process for the in situ formation and continuous feeding of high purity polycrystalline source. The CF-PVT system may be particularly useful for growing 3C silicon carbide. In some embodiments, ex situ data (e.g., operation parameters) may be obtained from the CF-PVT system and provided to a prediction model to determine a predicted in situ parameter (e.g., a predicted crystal parameter) of the crystal material 126 (e.g., crystalline material boule) and adjust one or more process parameters of the CF-PVT system based on the predicted in situ parameter (e.g., predicted crystal parameter). As indicated, the crystal growth system 112 may include an interface structure 1002. The interface structure 1002 may be graphite, such as porous graphite. The interface structure 1002 may include a baffle structure. The interface structure 1002 may include one or more apertures.

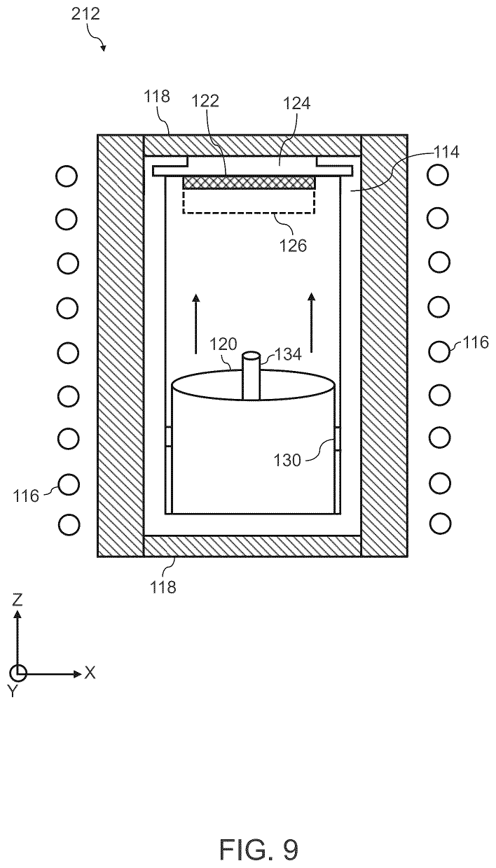

FIG. 9 depicts a cross-sectional diagram of an example crystal growth system 112 according to example aspects of the present disclosure. The crystal growth system 112 may be similar to that shown in FIG. 3A, but also includes an inlet 134 for introducing a dopant (e.g., N2) to the crystal growth chamber 114. The inlet 134, may be, for example, a tube, pipe, vent, or the like. In some embodiments, the source material 120 may surround the inlet 134. For example, in some embodiments, the source material structure may include a channel through which the inlet 134 is provided. In other embodiments, the source material structure may include a plurality of subcomponents (attached or detached) which surround the inlet 134. The inlet 134 may be connected to a dopant-containing gas source (not shown) and configured to introduce the dopant-containing gas to the crystal growth chamber 114. An example of a dopant-containing gas is nitrogen. In some embodiments, adjusting one or more process parameters of a crystal growth process may include adjusting a flow rate or quantity of dopant introduced to the crystal growth chamber 114 via the inlet 134.

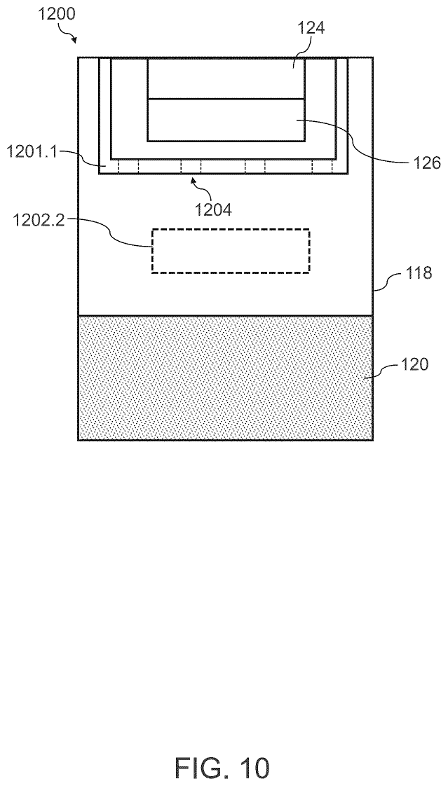

FIG. 10 depicts an example crystal growth system 1200 according to example embodiments of the present disclosure. In FIG. 10, the crystal growth system 1200 may include the interface structure 1202.1, the seed holder 124, the crystalline material 126, the crucible 118, and the source material 120. The interface structure 1202.1 may be positioned such that the interface structure 1202.1 extends around at least three sides of the crystalline material 126, with the longest dimension located below the crystalline material 126. The interface structure 1202.1, in this configuration, may be referred to as a shell structure as it provides a shell around the crystalline material 126. The interface structure 1202.1 may be graphite, such as porous graphite. The interface structure 1202.1 may include one or more apertures 1204 that assist in the transport of source vapor from the source material 120 to the seed holder 124. The interface structure 1202.1 may include a baffle structure. In some examples, the interface structure 1202.1 may or may not include any apertures 1204. The interface structure 1202.1 may be porous graphite and may have a porosity of greater than about 40%, such as greater than about 70%, such as in a range of 40% to 95%, such as in a range of 70% to 95%. The interface structure 1202.1 may be positioned such that the interface structure 1202.1 extends around at least three sides of the crystalline material 126, with the longest dimension located below the crystalline material 126. The system 1200 may include one or more second interface structure(s) 1202.2. The one or more second interface structure(s) 1202.2 may be arranged in the vapor transport path from the source material 120 to the crystalline material 126. The one or more second interface structure(s) 1202.2 may be graphite, such as porous graphite. The interface structure 1202.2 may include a baffle structure. The interface structure 1202.2 may include one or more apertures.

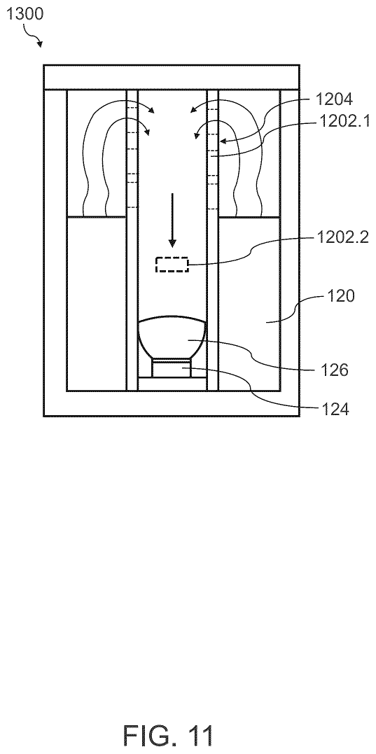

In FIG. 11, the crystal growth system 1300 may include the interface structure 1202.1, the seed holder 124, the crystalline material 126, the crucible 118, and the source material 120. The interface structure 1202.1 may include a tubular baffle structure. The crystalline material 126 may be within the interface structure 1202.1. The interface structure 1202.1 may be graphite, such as porous graphite. The interface structure 1202.1 may include one or more apertures 1204 that assist in the transport of source vapor from the source material 120 to the seed material 122. The system 1300 may further include one or more second interface structures 1202.2. The one or more second interface structures 1202.2 may be arranged in the vapor transport path between the source material 120 and the crystalline material 126. Source vapor may be transported through the interface structures 1202.1 and 1202.2. The one or more second interface structure(s) 1202.2 may be graphite, such as porous graphite. The interface structure 1202.2 may include a baffle structure. The interface structure 1202.2 may include one or more apertures.

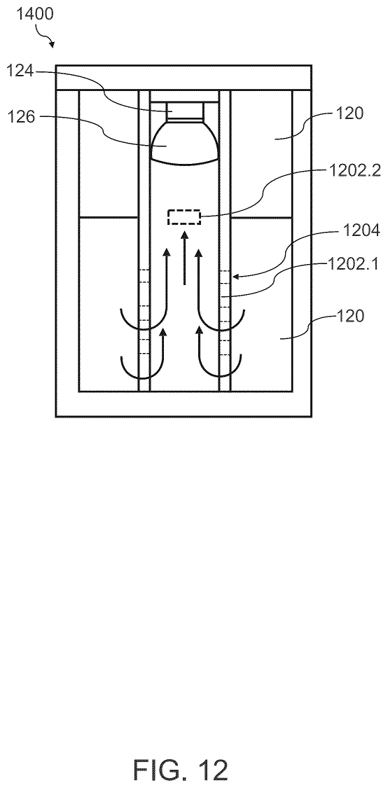

In FIG. 12, the crystal growth system 1400 includes the crystalline material 126 at the top of the crucible 118. Similar to FIG. 11, the interface structure 1202.1 may include a tubular baffle structure. The crystalline material 126 may be within the interface structure 1202.1. The interface structure 1202.1 may be graphite, such as porous graphite. The interface structure 1202.1 may include one or more apertures 1204 that assist in the transport of source vapor from the source material 120 to the crystalline material 126. The system 1300 may further include one or more second interface structures 1202.2. The one or more second interface structures 1202.2 may be arranged in the vapor transport path between the source material 120 and the crystalline material 126. Source vapor may be transported through the interface structures 1202.1 and 1202.2. The one or more second interface structure(s) 1202.2 may be graphite, such as porous graphite. The interface structure 1202.2 may include a baffle structure. The interface structure 1202.2 may include one or more apertures.

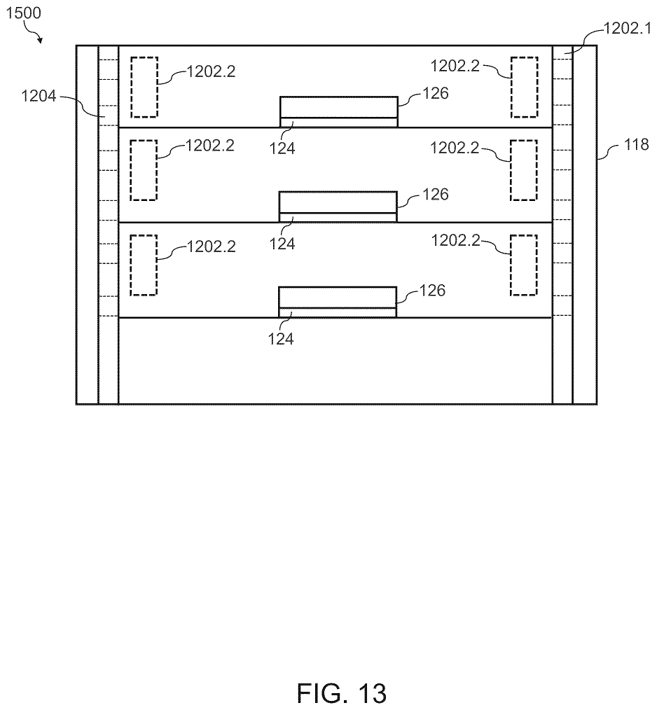

FIG. 13 depicts an example crystal growth system 1500 that may be used to grow a plurality of silicon carbide boules according to example embodiments of the present disclosure. In FIG. 13, the crystal growth system 1500 includes a plurality of seed holders 124 and crystalline material 126 arranged in different crystal growth chambers. The interface structure 1202.1 may separate the crystalline material 126 from the source material 120. As depicted in FIG. 13, the interface structure 1202.1 may include one or more apertures 1204 to assist with vapor transport from the source material 120 to the crystalline material 126. The crystal growth system 1500 may include one or more second interface structures 1202.2 in each chamber. The interface structure(s) 1202.2 may be arranged in the vapor transport path between the source material 120 and the crystalline material 126 in each chamber. Source vapor may be transported through the interface structure 1202.1 and/or the interface structure 1202.2. The one or more second interface structure(s) 1202.2 may be graphite, such as porous graphite. The interface structure 1202.2 may include a baffle structure. The interface structure 1202.2 may include one or more apertures.

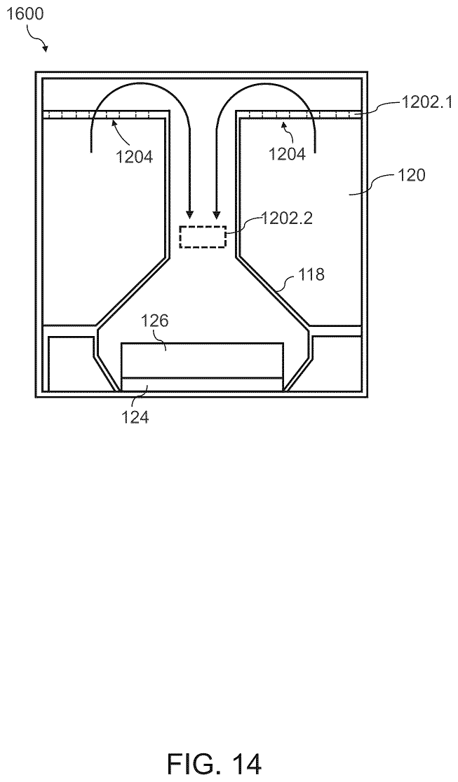

FIG. 14 depicts an example crystal growth systems 1600 according to example embodiments of the present disclosure. In FIG. 16, the crystal growth system 1600 includes the seed holder 124 and the crystalline material 126 arranged within a crucible 118. The crucible 118 may have one or more angled sidewalls. The crystal growth system 1600 includes a source material 120. The interface structure 1202.1 may be on top of the source material 120 and may separate the source material 120 from the reaction chamber defined by the crucible 118. As depicted in FIG. 16A, the interface structure 1202.1 may include one or more apertures 1204 to assist with vapor transport from the source material 120 to the crystalline material 126. The crystal growth system 1600 may include one or more second interface structures 1202.2. The interface structure(s) 1202.2 may be arranged in the vapor transport path between the source material 120 and the crystalline material 126. Source vapor may be transported through the interface structure 1202.1 and/or the interface structure 1202.2. The one or more second interface structure(s) 1202.2 may be graphite, such as porous graphite. The interface structure 1202.2 may include a baffle structure. The interface structure 1202.2 may include one or more apertures.

For any of the crystal growth systems provided herein, one or more parts of the crystal growth system or the source material may be 3D printed, such as disclosed in U.S. application Ser. No. 18/963,082, which is incorporated herein by reference. For instance, in some embodiments, the 3D printed source may include a silicon carbide powder and a binder (e.g., UV curable polymer adhesive). In some embodiments, the 3D printed part may include a ceramic material (e.g., silicon carbide, metal mixed with carbon, etc.) and a binder (e.g., UV curable polymer adhesive).

Example aspects of the present disclosure are set forth below. Any of the below features or examples may be used in combination with any of the embodiments or features provided in the present disclosure.

In an aspect, the present disclosure provides an example method. In some implementations, the example method includes obtaining, during a crystal growth process of a crystalline material, one or more ex situ parameters of a crystal growth system associated with the crystal growth process. In some implementations, the example method includes determining, based at least in part on the one or more ex situ parameters, a predicted in situ parameter. In some implementations, the example method includes adjusting, based at least in part on the predicted in situ parameter, one or more process parameters of the crystal growth process.

In some implementations of the example method, the crystalline material includes silicon carbide.

In some implementations of the example method, the one or more ex situ parameters comprise one or more operation parameters.

In some implementations of the example method, the one or more operation parameters comprise heating element temperature data.

In some implementations of the example method, the one or more operation parameters comprise heating element power consumption data.

In some implementations of the example method, the one or more operation parameters comprise one or more of chemical composition of species, mass flow of species, coolant temperature, coolant flow rate, insulation displacement, or pressure change.

In some implementations of the example method, the predicted in situ parameter includes a crystal parameter.

In some implementations of the example method, the crystal parameter includes crystal growth height or crystal growth rate.

In some implementations of the example method, the crystal parameter includes one or more of shape, doping, crystal stress, one or more optical properties of the crystalline material, or uniformity.

In some implementations of the example method, the predicted in situ parameter includes an insulation parameter.

In some implementations of the example method, the predicted in situ parameter includes a source parameter.

In some implementations of the example method, the predicted in situ parameter includes an interface structure parameter.

In some implementations of the example method, determining the predicted in situ parameter includes providing the one or more ex situ parameters to a machine-learning model. In some implementations of the example method, determining the predicted in situ parameter includes obtaining, from the machine-learning model, the predicted in situ parameter.

In some implementations of the example method, the machine-learning model is a physics-informed machine-learning model.

In some implementations of the example method, the physics-informed machine-learning model determines the predicted in situ parameter based at least in part on thermal leak modeling of the crystal growth system.

In some implementations of the example method, the machine-learning model is trained using ex situ data.

In some implementations of the example method, the machine-learning model is trained using heating element temperature data or heating element power consumption data.

In some implementations of the example method, adjusting the one or more process parameters includes determining a predicted crystal growth rate. In some implementations of the example method, adjusting the one or more process parameters includes comparing the predicted crystal growth rate to a target growth rate for the crystalline material. In some implementations of the example method, adjusting the one or more process parameters includes adjusting the one or more process parameters based on the target crystal growth rate and the predicted crystal growth rate.

In some implementations of the example method, the one or more process parameters comprise one or more of temperature, pressure, coolant flow rate, flux, growth segment time duration, heater position, crucible position, or crucible position relative to heater position, insulation position, crystal position, source position, or rotation of the crystal.

In some implementations of the example method, the predicted in situ process parameter includes a predicted doping of the crystalline material, wherein adjusting a process parameter includes adjusting a flow of dopants during a crystal growth process.

In an aspect, the present disclosure provides an example method. In some implementations, the example method includes obtaining ex situ data associated with a crystal growth system used to grow a crystalline material. In some implementations, the example method includes training a machine-learning model to predict an in situ parameter during a crystal growth process using the ex situ data associated with the crystal growth system.

In some implementations of the example method, the ex situ data includes data associated with operation of the crystal growth system.

In some implementations of the example method, the data associated with operation of the crystal growth system includes heating element temperature data or heater element power consumption data.

In some implementations of the example method, the ex situ data is associated with a plurality of crystal growth systems.

In some implementations, the example method includes generating model training data based on a correlation between the ex situ data and an in situ parameter.

In some implementations of the example method, the in situ parameter is a crystal parameter.

In some implementations of the example method, the crystal parameter includes crystal growth height or crystal growth rate.

In some implementations of the example method, the crystal parameter includes one or more of shape, doping, crystal stress, one or more optical properties of the crystalline material, or uniformity.

In some implementations of the example method, the in situ parameter includes an insulation parameter.

In some implementations of the example method, the in situ parameter includes a source parameter.

In some implementations of the example method, the in situ parameter includes an interface structure parameter.

In some implementations of the example method, the machine-learning model is a physics-informed machine-learning model.

In some implementations of the example method, the machine-learning model includes one or more neural networks.

In an aspect, examples of the present disclosure are directed to a system. The system includes processing circuitry configured to perform operations. The operation comprise: obtaining, during a crystal growth process of a crystalline material, one or more ex situ parameters of a crystal growth system associated with the crystal growth process; determining, based at least in part on the one or more ex situ parameters, a predicted in situ parameter; and adjusting, based at least in part on the predicted in situ parameter, one or more process parameters of the crystal growth process.

In some implementations of the example system, a seed holder configured to hold a seed crystal, the seed crystal providing a growth surface for growth of crystalline material; a crucible at least partially defining a crystal growth chamber; and a source material.

In some implementations of the example system, the crystalline material includes silicon carbide.

In some implementations of the example system, the one or more ex situ parameters comprise one or more operation parameters associated with operation of the system.

In some implementations of the example system, the one or more operation parameters comprise temperature data.

In some implementations of the example system, the one or more operation parameters comprise power consumption data.

In some implementations of the example system, the one or more operation parameters comprise one or more of chemical composition of species, mass flow of species, coolant temperature, coolant flow rate, insulation displacement, or pressure change.

In some implementations of the example system, the predicted in situ parameter includes a crystal parameter.

In some implementations of the example system, the crystal parameter includes crystal growth height or crystal growth rate.

In some implementations of the example system, the crystal parameter includes one or more of shape, doping, crystal stress, one or more optical properties, or uniformity.

In some implementations of the example system, the predicted in situ parameter includes an insulation parameter.

In some implementations of the example system, the predicted in situ parameter includes a source parameter.

In some implementations of the example system, the predicted in situ parameter includes an interface structure parameter.

In some implementations of the example system, operation of determining the predicted in situ parameter includes providing the one or more ex situ parameters to a machine-learning model. In some implementations of the example system, operation of determining the predicted in situ parameter includes obtaining, from the machine-learning model, the predicted in situ parameter.

In some implementations of the example system, the machine-learning model is a physics-informed machine-learning model.

In some implementations of the example system, the physics-informed machine-learning model determines the predicted in situ parameter based at least in part on thermal leak modeling of the crystal growth system.

In some implementations of the example system, the one or more process parameters comprise one or more of temperature, pressure, coolant flow rate, flux, growth segment time duration, heater position, crucible position, or crucible position relative to heater position, insulation position, crystal position, source position, or rotation of the crystal.

In an aspect, the present disclosure provides an example method. In some implementations, the example method includes obtaining, during a crystal growth process of a crystalline material, one or more operation parameters of a crystal growth system associated with the crystal growth process. In some implementations, the example method includes determining, based on the one or more operation parameters, a predicted crystal parameter. In some implementations, the example method includes adjusting, based on the predicted crystal parameter, one or more process parameters of the crystal growth process.

In some implementations of the example method, the crystalline material includes silicon carbide.

In some implementations of the example method, the predicted crystal parameter includes a predicted growth height.

In some implementations of the example method, the predicted crystal parameter includes a predicted growth rate.

In some implementations of the example method, the one or more operation parameters comprise temperature of one or more components of the crystal growth system.

In some implementations of the example method, determining the predicted crystal parameter includes providing the one or more operation parameters to a machine-learning model for predicting crystal parameters. In some implementations of the example method, determining the predicted crystal parameter includes obtaining, from the machine-learning model, the predicted crystal parameter.

In some implementations of the example method, the machine-learning model is a physics-informed machine-learning model.

In some implementations of the example method, the physics-informed machine-learning model determines the predicted crystal parameter based on thermal leak modeling of the crystal growth system.

In some implementations of the example method, adjusting the one or more process parameters includes determining a predicted growth rate. In some implementations of the example method, adjusting the one or more process parameters includes comparing the predicted growth rate to a target growth rate for the crystalline material. In some implementations of the example method, adjusting the one or more process parameters includes adjusting the one or more process parameters based on the target growth rate and the predicted growth rate.

In some implementations of the example method, the one or more process parameters comprise one or more of temperature, pressure, coolant flow rate, flux, growth segment time duration, heater position, crucible position, or crucible position relative to heater position, insulation position, crystal position, source position, or rotation of the crystal.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A method comprising:
obtaining, during a crystal growth process of a crystalline material, one or more ex situ parameters of a crystal growth system associated with the crystal growth process;
determining, based at least in part on the one or more ex situ parameters, a predicted in situ parameter; and
adjusting, based at least in part on the predicted in situ parameter, one or more process parameters of the crystal growth process.

2. The method of claim 1, wherein the crystalline material comprises silicon carbide.

3. The method of claim 1, wherein the one or more ex situ parameters comprise one or more operation parameters.

4. The method of claim 3, wherein the one or more operation parameters comprise heating element temperature data.

5. The method of claim 3, wherein the one or more operation parameters comprise heating element power consumption data.

6. The method of claim 3, wherein the one or more operation parameters comprise one or more of chemical composition of species, mass flow of species, coolant temperature, coolant flow rate, insulation displacement, or pressure change.

7. The method of claim 1, wherein the predicted in situ parameter comprises a crystal parameter.

8. The method of claim 7, wherein the crystal parameter comprises crystal growth height or crystal growth rate.

9. The method of claim 7, wherein the crystal parameter comprises one or more of shape, doping, crystal stress, one or more optical properties of the crystalline material, or uniformity.

10. The method of claim 1, wherein the predicted in situ parameter comprises an insulation parameter.

11. The method of claim 1, wherein the predicted in situ parameter comprises a source parameter.

12. The method of claim 1, wherein the predicted in situ parameter comprises an interface structure parameter.

13. The method of claim 1, wherein determining the predicted in situ parameter comprises:
providing the one or more ex situ parameters to a machine-learning model; and
obtaining, from the machine-learning model, the predicted in situ parameter.

14. The method of claim 13, wherein the machine-learning model is a physics-informed machine-learning model.

15. The method of claim 14, wherein the physics-informed machine-learning model determines the predicted in situ parameter based at least in part on thermal leak modeling of the crystal growth system.

16. The method of claim 1, wherein the crystal growth process is associated with a temperature of about 2000 degrees Celsius or greater.

17. The method of claim 1, wherein adjusting the one or more process parameters comprises:
determining a predicted crystal growth rate;
comparing the predicted crystal growth rate to a target growth rate for the crystalline material; and
adjusting the one or more process parameters based on the target crystal growth rate and the predicted crystal growth rate.

18. The method of claim 1, wherein the one or more process parameters comprise one or more of temperature, pressure, coolant flow rate, flux, growth segment time duration, heater position, crucible position, or crucible position relative to heater position, insulation position, crystal position, source position, or rotation of the crystal.

19. The method of claim 1, wherein the predicted in situ process parameter comprises a predicted doping of the crystalline material, wherein adjusting a process parameter comprises adjusting a flow of dopants during a crystal growth process.

20. A system, the system comprising:
processing circuitry configured to perform operations, the operations comprising: obtaining, during a crystal growth process of a crystalline material, one or more ex situ parameters of a crystal growth system associated with the crystal growth process;
determining, based at least in part on the one or more ex situ parameters, a predicted in situ parameter; and
adjusting, based at least in part on the predicted in situ parameter, one or more process parameters of the crystal growth process.
